(19) United States
(12) Patent Application Publication
(10) Pub. No.: US 2026/0073980 A1
(43) Pub. Date: Mar. 12, 2026

(54) USING PHASE CHANGE MEMORY (PCM) DRIFT TO ERASE HYPERDIMENSIONAL (HD) MODEL FOR SECURE EDGE COMPUTING

(71) Applicant: International Business Machines Corporation, Armonk, NY (US)

(72) Inventors: Nanbo Gong, White Plains, NY (US); HsinYu Tsai, Cupertino, CA (US); Charles Mackin, San Jose, CA (US); Steven Holmes, Red Hook, NY (US)

(21) Appl. No.: 18/827,662

(22) Filed: Sep. 6, 2024

(51) Int. Cl. G11C 13/00

(52) U.S. Cl. CPC G11C 13/0004; G11C 13/004; G11C 13/0059; G11C 13/0069; G11C 2213/30

(57) ABSTRACT

A system includes a memory array. The memory array includes a plurality of word lines; a plurality of bit lines intersecting the plurality of word lines at a plurality of cell locations; and a plurality of cells respectively located at the plurality of cell locations. Each cell of the plurality of cells in turn includes: a first phase change memory device having a first drift; and a second phase change memory device having a second drift. The first drift is higher than the second drift.

### BACKGROUND

The present invention relates generally to the electrical, electronic and computer arts and, more particularly, to phase change memories, hyperdimensional computing, and edge computing devices.

Phase-change memory is a type of non-volatile random-access memory that takes advantage of the unique behavior of phase change materials such as chalcogenide glass, where heat from a heating element is used to either quickly heat and quench the material, making it amorphous, or to hold it in its crystallization temperature range for some time, thereby switching it to a crystalline state.

Hyperdimensional (HD) computing is promising as compared to conventional deep neural networks (DNN) training. HD computing employs orthogonal high-dimensional distributed representations, is explainable, and exhibits robustness to noise. Advantageously, there is no need for power-hungry training of neural networks (NN).

As the name implies, edge computing devices are located near the edge of a network, near consumers and/or data sources. They can often function without needing a full connection to a central network, and are pertinent for real-time applications and internet-of-things (IoT) deployments. While the deployment of millions of edge devices can be quite advantageous, care should be taken since each edge device is a potential entry points for bad actors.

### BRIEF SUMMARY

Principles of the invention provide techniques for using phase change memory (PCM) drift to erase hyperdimensional (HD) model for secure edge computing. In one aspect, an exemplary system includes a memory array. The memory array includes a plurality of word lines; a plurality of bit lines intersecting the plurality of word lines at a plurality of cell locations; and a plurality of cells respectively located at the plurality of cell locations. Each cell of the plurality of cells in turn includes: a first phase change memory device having a first drift; and a second phase change memory device having a second drift. The first drift is higher than the second drift.

In another aspect, an exemplary semiconductor structure includes method of operating a phase change memory array. The method includes providing a phase change memory array. The phase change memory array includes a plurality of word lines; a plurality of bit lines intersecting the plurality of word lines at a plurality of cell locations; and a plurality of cells respectively located at the plurality of cell locations. Each cell of the plurality of cells in turn includes at least one phase change memory device having a predetermined drift. Further steps include programming the phase change memory array with a model including a plurality of zeroes and ones; carrying out inferencing with the programmed array for no more than a predetermined time period; and deliberately allowing the ones to degrade to zeroes after the predetermined time period due to the predetermined drift to prevent further inferencing after the predetermined time period has elapsed.

In still another aspect, an exemplary system includes a memory array. The memory array includes a plurality of word lines; a plurality of bit lines intersecting the plurality of word lines at a plurality of cell locations; and a plurality of cells respectively located at the plurality of cell locations. Each cell of the plurality of cells in turn includes at least one phase change memory device having a predetermined drift. Also included are a model control coupled to the word lines and an array program and read circuit coupled to the bit lines. The model control and the array program and read circuit are cooperatively configured to cause: the phase change memory array to be programmed with a model including a plurality of zeroes and ones, wherein the zeroes and ones are both programmed in a near-reset state; and the phase change memory array to carry out inferencing with the programmed array for no more than a predetermined time period. Thus, the phase change memory array is able to carry out accurate inferencing with the programmed array for no more than a predetermined time period because the ones degrade to zeroes after the predetermined time period due to the predetermined drift to prevent further inferencing after the predetermined time period has elapsed.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
a larger array size and lower power PCM as compared to the prior art because of novel logic 0 and logic 1 definition near the reset state provides low power operation, and IR (I=current, R=resistance) voltage drop benefit, due to higher resistance across the array;
capability to forget the model, which provides significant security benefits for edge computing applications and the like; and
flexibility to choose to forget the model “fast” or “slow,” depending on mode, to program PCM devices—this provides additional benefits to have flexibility to forget the model depending on considerations of both inference application and security.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1 and 2 show aspects of programming an array in accordance with aspects of the invention;

FIG. 3 shows a PCM array in accordance with an aspect of the invention;

FIG. 4 shows another PCM array in accordance with another aspect of the invention;

FIG. 5 show aspects of a two-device cell wherein one device has a liner and one does not have a liner;

FIG. 6 show aspects of a two-device cell wherein one device employs GST and one employs a superlattice;

FIG. 7 shows yet another PCM array in accordance with yet another aspect of the invention;

FIG. 8 compares programming in accordance with an aspect of the invention compared with the prior art; and

FIG. 9 depicts a computing environment according to an embodiment of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As noted, HD computing is promising as compared to conventional DNN training; it employs orthogonal high-dimensional distributed representations, is explainable, and exhibits robustness to noise. Advantageously, in HD computing, there is no need for power-hungry training of neural networks (NN). Furthermore, as also noted, the deployment of millions of edge devices can be quite advantageous, but care should be taken since each edge device is a potential entry points for bad actors. Because of the potential for security breaches to edge devices, it is desirable for such devices to have the capability to “forget.” Advantageously, one or more embodiments have the capability to automatically erase the HD model after a period of time.

Heretofore, the unit cell in a PCM memory array typically uses only a single type of PCM, and seeks to improve accuracy by the reduction in drift. The array of PCM devices includes peripheral circuitry such as wordline drivers, an analog-to-digital (A/D) converter array, and the like to utilize the full set and reset PCM range for logical 0 and logical 1, and seeks to mitigate drift by avoiding use of high-drift PCM material. In prior art devices, the dynamic range lies between the resistance of the logical 1 value and the lowest resistance of the logical zero value (the resistance of the logical zero value drifts upwards over time).

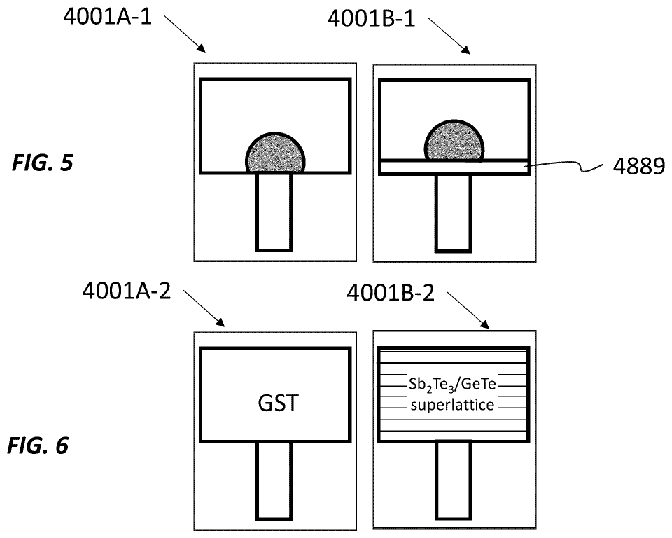

In contrast, some exemplary embodiments include a unit cell that include two types of PCM; a first type that has high drift, and a second type that has low drift. One or more embodiments program PCM near the reset state, seek to use high drift material, and provide a configuration where a unit cell can have a liner or no liner (see discussion of FIG. 5 below). One or more embodiments also provide potential low power operation and IR (I=current, R=resistance) voltage drop benefit due to higher resistance across the array.

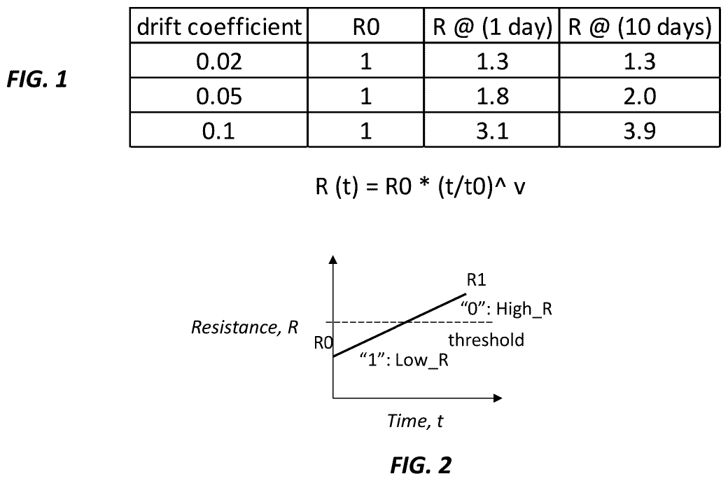

As noted, one or more embodiments program PCM near the reset state. PCM has a reset state (high resistance, with high drift coefficient) and a set state (low resistance, and low drift coefficient). Traditionally, PCM is programmed into full reset or full set to serve as memory (0 or 1 representation). In one or more embodiments, program to near reset for 0 and 1 (see FIGS. 1 and 2) and this provides benefits to use high drift coefficient near reset to forget the model.

One or more embodiments accordingly include both high drift and low drift PCM devices in a unit cell, program a PCM into a near-reset state as logic 1, and/or use drift to obtain logic 0 to forget information for security purposes as well.

One or more embodiments accordingly provide a PCM array with an HD encoding system and peripheral circuits to read a near reset condition as logic 1 and an after drift condition as logic 0. In some instances, a PCM device with a drift coefficient (e.g., 0.002-0.2), can be engineered by giving attention to the material and structure of the PCM. In some instances, the entire array begins with the high resistance state (e.g. program all the cells, and wait for one day or other appropriate predetermined time period).

In some cases, the encoding system only programs selected PCM cells for one time encoding. To “forget” faster, it is possible to program a selected PCM cell into a near reset state (i.e., R0). It is also possible to flexibly program a PCM cell into any state between reset and set, if a lower drift is desired (i.e., “forget” slower).

In one or more embodiments, un-refreshed PCM cells remain in the high resistance (HR) state, while refreshed ones move into the low resistance (LR-near reset or set) state, based on the HD encoding. Due to drift, however, refreshed PCM cells gradually become HR again, resulting in lost information.

In another aspect, a PCM array is provided with an HD encoding system, and a unit cell includes two PCM devices. The first PCM device has high drift, and the second PCM device has low drift. The first PCM device has no liner, and the second PCM device does have a liner. The second PCM device can be a superlattice, for example.

In still another aspect, the HD model can be extended to other DNN models, such as Residual Networks (“ResNet,”such as ResNet-32 or the like).

Consider now aspects of erasing information. If a pure digital approach were to be taken, the use of static random access memory (SRAM) or dynamic random access memory (DRAM) could be problematic, because there would be insufficient time to perform inference before erasing the model. The HD system requires a high dimension vector representation; i.e., a high density memory array with enough memory window is needed. SRAM/DRAM costs area, and is not able to achieve area-efficiency in scaled dimensions. Advantageously, one or more embodiments provide an approach with sufficient but limited retention: after initial HD model programming, with the device at R0, and after enough time (e.g. 1-10 days) to perform inference, the device shifts into the R1 state that has a detectable change compared to R0 (i.e., flips high H and low L—for example, 3-5× change in resistance).

Heretofore, in the use of PCM in HD computing, a similarity dot product is performed using in-memory computing (PCM). PCM (set as logic 1, reset as logic 0) is used to represent weights, which requires a low drift PCM. Prior art techniques have not focused on erasing the model. One or more embodiments employ high drift PCM to deliberately forget information to enhance security, programming near reset as logic 0, and allowing the device to drift into a higher resistance state. Indeed, one or more embodiments use PCM drift to erase information in an HD model for secure edge computing. One or more embodiments use resistance R@time “t” as high resistance (logic 0), and resistance R@t0 (initial time) as low resistance (logic 1). One or more embodiments initialize all PCM devices to logic 0, and only refresh needed PCM devices into logic 1. Logic 1 PCM devices eventually become logic 0 due to drift, and forget the model. In some embodiments, the unit cell includes two PCM devices, a first with high drift, and a second with low drift.

It has been shown that when random errors (more than 50%) occur, even in the case of an HD model (which is known to be robust), the model will be forgotten. PCM is promising for high-density back end of line (BEOL) compatible arrays, and is non-volatile. Conventionally, PCM has been programed into set (logic 1) or reset (logic 0). Drift is a common issue in conventional PCMs; it has been possible to mitigate the effect using a drift compensation approach. PCM drift depends on material, device structure, and also reset/set state. Heretofore, efforts have not been made to program the PCM into a near reset state as logic 1, and to use the drift in the reset state to erase information in an HD model.

Turning now to FIGS. 1 and 2, one or more embodiments use the resistance, R, at time t as the high resistance (logic 0), and use the R value at the initial time t0 as the low resistance (logic 1). This is different than the conventional use of reset as high resistance and set as low resistance. This demonstrates that it is feasible and flexible to enable a PCM array with desired drift to erase information in accordance with aspects of the invention. The table of FIG. 1 shows initial resistance R0 (normalized to 1) at initial non-zero time t0, as well as values after 1 day and 10 days for three different drift coefficients v. FIG. 2 shows resistance plotted against time.

In the non-limiting example of FIG. 1, the non-zero initial time t0 is taken as 1 second. For the “1 day” column, one day is 24 hours by 60 minutes/hour by 60 second/minute, or 86,400 seconds. For the “10 days” column, 10 days are 10×86,400 seconds=864,000 seconds. With t taken in seconds, R0 normalized to 1, and t0 of 1 second, R(t)=t^{v}. For the first row, R(t)=t^{0.02}; for the second row, R(t)=t^{0.05}; and for the last row, R(t)=t^{0.1}.

The use of the near reset state provides benefits including high drift, leading to a shorter time to erase information (and thus more security); and high resistance, leading to less leakage (and thus less stand-by power consumption) and also suitability for larger arrays (i.e., less IR drop effect). However, it is also possible to use the other state, if the user would like to keep information longer (before triggering the threshold due to lower drift).

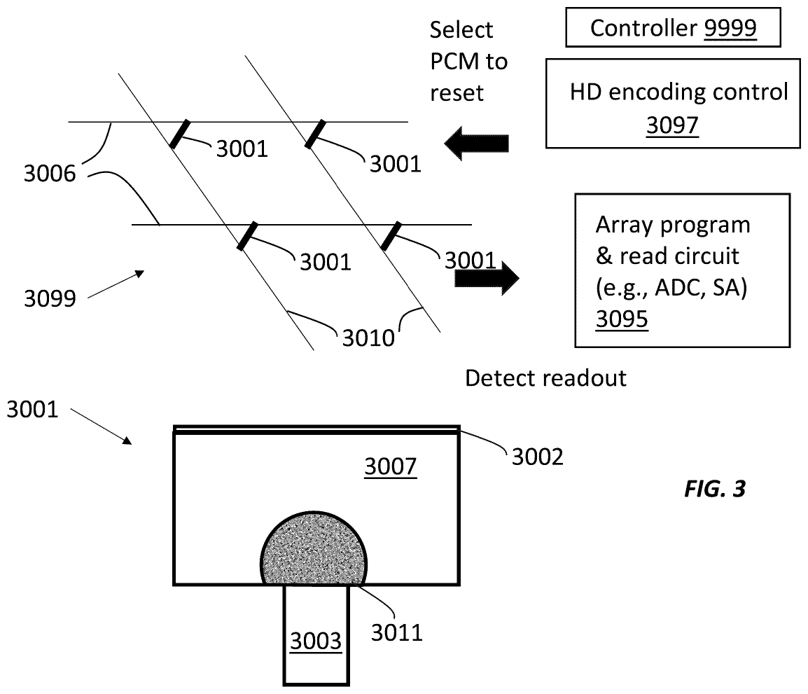

FIG. 3 shows a first PCM cell and array in accordance with aspects of the invention. Note the bottom electrode 3003. In one or more embodiments, the PCM cell 3001 includes a top electrode 3002 on the top surface of 3007, and a phase change material 3011/3007. The phase change material 3011/3007 can include a first portion 3011 (amorphous) and/or a second portion 3007 (crystalline) depending on its state. FIG. 3 also shows a PCM array 3099 with a plurality of bit lines 3010 and a plurality of word lines 3006 that intersect the plurality of bit lines at a plurality of cell locations. A plurality of PCM cells 3001 are located at each of the plurality of cell locations and connected between the bit lines and word lines through the top and bottom electrodes. In one or more embodiments, each of the cells is electrically connected to a corresponding bit line and selectively grounded under control of a corresponding one of the word lines (such as by a field effect transistor turned off or on by a signal from the word line applied to its gate). The HD encoding control 3097 can be coupled to the word lines 3006 to select cells (e.g., for reset). The array program and read circuit 3095 can be coupled to the bit lines 3010 and include A/D converters, shifters, summers, sense amplifier(s) (SA), etc. to program the cells and read out inferencing results.

Still referring to FIG. 3, aspects of the embodiment depicted therein include a finite time and secure HD system based on PCM. The PCM array 3099 is provided with an HD encoding system 3097 and peripheral circuits 3095 to read the PCM device(s) 3001. Device(s) 3001 can have a drift coefficient (e.g., 0.002-0.2), which can be engineered by the material and structure of the PCM. In one or more embodiments, the whole array begins with a HIGH resistance state (e.g. program all the cells HIGH, and wait for one day or other predetermined time period). In the example, the encoding system 3097 only programs selected PCM cells for one-time encoding. To “forget” faster, for security, programming is carried out to selected PCM cells into a near reset state (i.e., R0). Flexible programming of the PCM into any state between reset and set can be carried out, if it is desired to lower the drift (i.e., to “forget” slower). The un-refreshed PCM cells remain in a high resistance (HR) state, while the refreshed cells are in a low resistance (LR) (near reset or set) state, based on the HD encoding. Due to drift, the refreshed PCM cells gradually becomes HR again, resulting in lost information (desirable for security).

It should be understood that portions 3011/3007 are the same material, and that the presence of portion 3011 depends on the state of the device (i.e., if the GST or other PCM is amorphized into RESET (high resistance), then portion 3011 is present). The PCM cell can be disposed after front end of line (FEOL) process, and with back end of line (BEOL) wiring to form array 3099.

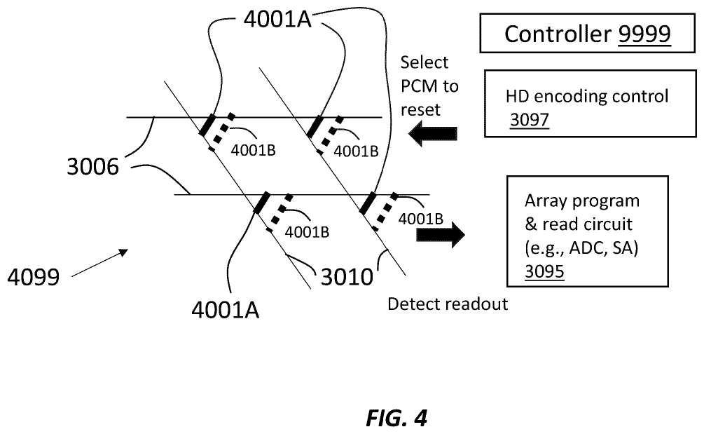

Referring now to FIGS. 4, 5, and 6, in another aspect of the invention, each cell location includes one PCM 4001A that has high drift and one PCM 4001B that has low drift. In FIG. 4, elements in array 4099 similar to array 3099 of FIG. 3 have the same reference number. The solid lines represent high-drift PCM cells 4001A while the dotted lines represent low-drift PCM cells 4001B. Several techniques can be used to implement the high-drift PCM cells 4001A and the low-drift PCM cells 4001B. In the approach of FIG. 5, note the high-drift PCM cells 4001A-1 and the low-drift PCM cells 4001B-1. In this aspect, the high-drift cell 4001A-1 does not have a liner while the low-drift cell 4001B-1 has a PCM liner 4889. In the approach of FIG. 6, note the high-drift PCM cells 4001A-2 and the low-drift PCM cells 4001B-2. In this aspect, the high-drift cell 4001A-2 employs GST as the phase-change material while the low-drift cell 4001B-2 uses a Sb₂Te₃/GeTe superlattice. Advantages of the embodiments of FIGS. 4-6 over prior art systems with only high-drift PCM or only low-drift PCM include that only the high drift PCM forgets soon, while the low drift PCM can be used to remember information, although it lacks secure erase capability. This aspect provides flexibility to program the unit cell with three modes covering easy-to-forget to robust information in the system, depending on the user's needs. Advantages of the embodiments of FIGS. 4-6 (e.g., over two separate arrays, one array with a PCM with no liner and one with a PCM with a liner), include reduced communication between arrays, latency/power benefits, and the fact that the local unit cell weight representation is less affected by IR drop and the like in a large array, thus implying the system being more suitable for high density HD models.

The skilled artisan will have general familiarity with the use of liners and superlattice materials to provide drift mitigation (the liner or superlattice provide low drift coefficient), and, given the teachings herein, can adapt same to implement one or more embodiments.

Thus, continuing to refer to FIGS. 4-6, an exemplary structure includes a PCM array 4099 with an HD encoding system 3097, where each unit cell includes two PCM devices 4001A, 4001B. The first PCM 4001A has high drift, and the second PCM 4001B has low drift. As shown in FIG. 5, in some instances, the first PCM 4001A-1 has no liner, while the second PCM 4001B-1 has liner 4889. As shown in FIG. 6, in some instances, the first PCM 4001A-2 uses GST as the PCM, while the second PCM 4001B-2 employs a superlattice structure.

It should be understood that GST is useful as a medium of storage or memory given its ability to affect a reversible phase change when melted and quenched rapidly, or heated above crystalline temperature (but not melted), switching between an amorphous state and a crystalline state. One non-limiting exemplary GST composition is germanium-antimony-tellurium or Ge₂Sb₂Te₅.

Furthermore, still continuing to refer to FIGS. 4-6, an exemplary method includes reading to detect a difference between the two PCM devices, as a read-out of the given unit cell. The whole array can begin with a high resistance state (e.g., program all cells, and wait for one day). In one or more embodiments, the encoding system 3097 only programs selected PCM cells (e.g., only program the no liner PCM device 4001A-1, do not program the liner PCM 4001B-1) for one time encoding. In Mode A, to “forget” faster, program the selected PCM into a near reset state (i.e., R0). In Mode B, the system can also program the no liner PCM into a near set state, if lower drift is desired (i.e., “forget” slower). In another mode (Mode C, for an even more stable model), to program the unit cell, only program the liner PCM, do not program the no liner PCM (leave it as a reference). In this aspect, the model remains even more stable than the no liner PCM near the SET case (Mode B).

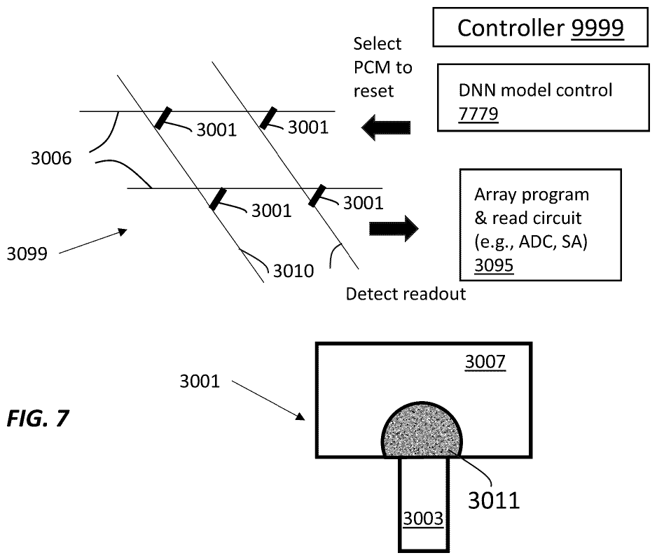

Referring now to FIG. 7, in another aspect, the HD model can also be extended into other DNN models, such as ResNet-32, long short-term memory (LSTM), transformer-based models, and the like. In FIG. 7, elements similar to those in FIG. 3 have the same reference number. Instead of HD coding control 3097, the embodiment of FIG. 7 includes DNN model control 7779. Considering the feasibility of erase information of beyond HD models (e.g. ResNet-32), in one or more embodiments, drifts into high resistance trigger a threshold, similar to stuck-at-open behavior. It has been found that ˜10% of information loss leads to almost 0.5 error, indicating that exemplary erase information methods disclosed herein can lead to the successful forgetting of information for security purposes. In one or more embodiments, for DNN models other than HD models, the 0, 1 weight representations are done in the same manner—as in the HD example, 0, 1 are both defined in a near-reset state. The model architecture will be different as will be apparent to the skilled artisan, who will have general familiarity with a variety of models such as HD, ResNet, LSTM, and the like as set forth herein. Given the teachings herein, the skilled person can adapt inventive techniques for encoding both zeroes and ones in a near-reset state to implement security via forgetting.

It is worth noting that temperature is a pertinent factor to consider with regard to resistance drift, and drift rate can be back extrapolated. However, these aspects are significant only when the time is not too long after weight programming; i.e., HD or DNN inference should still work and the drifted conductance is still close to the programming value to be extracted as 1 or 0. One or more embodiments are directed to a model self-erasing slowly over time, hence providing additional security. In that scenario, temperature variation helps erase the model faster and backward conductance extrapolation will no longer be possible after a certain time. Furthermore, even at early stage after programming, we believe that it will be almost impossible to reverse engineer the weights from a 10-k HD model, and obtain an absolutely correct readout each time in order to precisely predict the drift coefficient of each device. Even further, temperature dependence of resistance drift can vary depending on the temperature range, which poses even more difficulty to a bad actor to hack the devices to perform backward extrapolation, and provides better security due to self-erasing.

Regarding concerns about the use of a near Reset for a logic “0” reducing the dynamic range between a “0” and a “1” and thus making the system more prone to fail due to noise, dynamic range is important. It is also worth mentioning that the dynamic range requirement is application-specific, and the HD system is known to be noise tolerant. In addition to that, how close it is necessary to be to RESET depends on the time period in which it is desired for the data to be erased. Referring again to FIG. 1, consider a simple estimate dynamic range compression as a function of how long it is desired for the network to last. In a non-limiting example, for a system that is desired to last longer than one day, all that is needed is a drift coefficient that is around 0.1, with an on-off of about 3×. While choosing somewhere between fully reset and fully set can reduce dynamic range a bit, but the skilled artisan, given the teachings herein, will be able to engineer a system in accordance with aspects of the invention to tolerate noise, especially for the HD system.

In the case of the pair of PCMs, one with a liner, and one without, there may be concerns that the pair may work as suggested if the liner device is programmed close to the full Reset state; and that, for the intermediate state, the liner device is also drifting. Furthermore, there may be concerns that the PCM device has a reduced dynamic range so that the second device cannot be programmed too close to Reset. However, it should be clarified that one or more embodiments only program one device and leave the other device as a reference. Referring again to FIGS. 4 and 5, in one or more embodiments, in mode A and mode B, program the selected no liner device but leave the liner device as a reference. If an even more stable system than that is desired, compared to mode B, consider also mode C, which programs only the liner device but leaves the no liner device as a reference. In this way, it is possible to maintain flexibility to have a very easy-to-forget system, and also a robust system based on the unique unit cell. As for dynamic range, we have found about 3-4 is adequate to ensure accuracy, depending on the network type, for various models within a reasonable noise range.

One or more embodiments use PCM drift to automatically prevent data leakage of an HD model (or other model such as DNN). One or more embodiments provide techniques to use PCM drift to erase information to automatically prevent data leakage (there is no need in one or more embodiments to identify an erase event) with flexibility to control how long it is desired to keep the data, which provides significant security benefits for edge computing. PCM drift is resistance state dependent, which provides flexibility of weight erase in DNN and HD models and the like. While the drift is always there, one or more embodiments overcome the need for complex erase procedures to erase information for security applications. One or more embodiments provide a PCM array with HD encoding system and peripheral circuits to read near reset as logic 1 and after drift as logic 0. Advantageously, this makes sure that all PCM cells are around the high resistance state, and therefore shows low leakage and power benefits over conventional full resistance range of PCM from prior art. PCM drift is an intrinsic feature of PCM devices. One or more embodiments provide improvements in power consumption and security (because of the drift in PCM) for edge computing and the like. One or more embodiments do not use DRAM, which saves power. One or more embodiments program near reset as logic 1 and after drift as logic 0, which further improves power saving compared to prior art approaches that program PCM to the full range (set to reset). Using a PCM array to program near reset as logic 1 and after drift as logic 0 in accordance with one or more embodiments further improves resistance across the PCM array into the higher level, and therefore shows power and IR drop benefits, suitable for larger arrays. Indeed, one or more embodiments provide techniques to use near reset PCM as logic 1 and after drift as logic 0, and to employ that for flexible model erasure and enhanced security for edge computing.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with conventional techniques that can be adapted to form the starting structure, and with conventional techniques, such as lithography and etching, that can be adapted to carry out the patterning. The skilled artisan will be familiar with suitable materials for insulators (e.g., SiO₂), further metallization (e.g., copper with liners/barriers such as Ta, TaN), and the like.

Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary system includes a memory array. The memory array includes a plurality of word lines 3006 and a plurality of bit lines 3010 intersecting the plurality of word lines at a plurality of cell locations. A plurality of cells are respectively located at the plurality of cell locations. Each cell of the plurality of cells in turn includes a first phase change memory device 4001A having a first drift, and a second phase change memory device 4001B having a second drift. The first drift is higher than the second drift.

Referring to FIG. 5, in some cases, the first phase change memory device 4001A-1 does not have a liner and the second phase change memory device 4001B-1 has a liner 4889.

Referring to FIG. 6, in some cases, the first phase change memory device 4001A-2 includes GST phase change material and the second phase change memory device 4001B-2 includes superlattice phase change material.

As shown, for example, in FIG. 4, in one or more embodiments, the first and second phase change memory devices are connected in parallel and each of the cells is electrically connected to a corresponding bit line and selectively grounded under control of a corresponding one of the word lines (e.g., by energizing a field effect transistor gate with the corresponding word line for selective grounding, in a known manner).

One or more embodiments further include a model control 3097, 7779 coupled to the word lines and configured to select given ones of the cells for reset. One or more such embodiments further include an array program and read circuit 3095 coupled to the bit lines and configured to program the cells and read out inferencing results.

As noted, in a non-limiting example, the model control includes a hyperdimensional (HD) encoding control 3097.

In one or more embodiments, the first and second phase change memory devices each include a top electrode 3002, a bottom electrode 3003, and phase change material 3007, 3011.

In one or more embodiments, the array program and read circuit is further configured to program the cells with weights represented by a difference between the first and second phase change memory devices. For example, the first and second devices have respective conductances g₁ and g₂, and the weight is proportional to g₁-g₂. This approach advantageously allows covering both plus and minus values for good dynamic range.

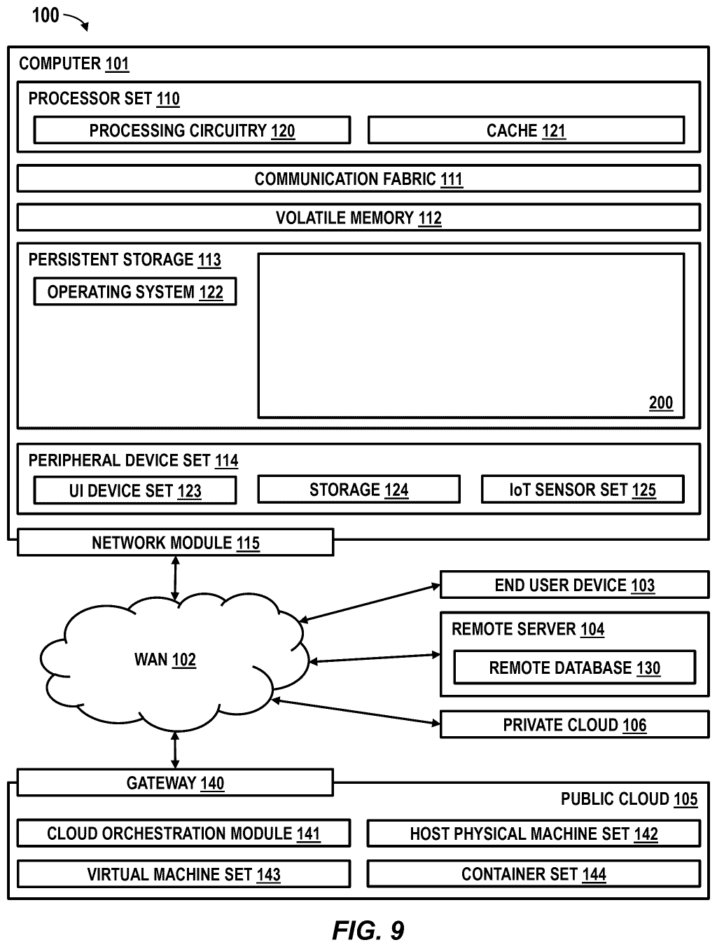

One or more embodiments further include a network, where the memory array is located on an edge computing device that is coupled to the network (and can be used, for example, for an edge application that runs on this edge computing device/end user device and not in the cloud). This is a non-limiting example, however, since embodiments of the invention can be used both for in-cloud applications and edge applications. For example, referring to FIG. 9, the memory array could be on an end user device 103 or within the public cloud 105.

One or more embodiments can also include an additional controller 9999 besides the HD encoding control 3097/DNN model control 7779 and the array program and read circuit 3095. This controller can be implemented, for example, in digital circuitry as described elsewhere herein and can be utilized for known functions such as programming, reading, writing, and verification. Controller 9999 can be coupled to the HD encoding control 3097/DNN model control 7779 and/or the array program and read circuit 3095 and can be integral with or separate from such components.

In another aspect, a method of operating a phase change memory array includes providing a phase change memory array. The array includes a plurality of word lines 3006 and a plurality of bit lines 3010 intersecting the plurality of word lines at a plurality of cell locations. A plurality of cells are respectively located at the plurality of cell locations. Each cell of the plurality of cells in turn includes at least one phase change memory device such as 3001 having a predetermined drift. Further steps include programming the phase change memory array with a model including a plurality of zeroes and ones; carrying out inferencing with the programmed array for no more than a predetermined time period; and deliberately allowing the ones to degrade to zeroes after the predetermined time period due to the predetermined drift to prevent further inferencing after the predetermined time period has elapsed.

In a non-limiting example, in the step of programming the phase change memory array with the model, the model includes a hyperdimensional (HD) model.

On the other hand, in other non-limiting embodiment(s), in the step of programming the phase change memory array with the model, the model includes a deep neural network (DNN) model selected from the group consisting of a residual neural network, a long short-term memory, and a transformer-based model.

One or more embodiments further include locating the phase change memory array on an edge computing device that is coupled to a network.

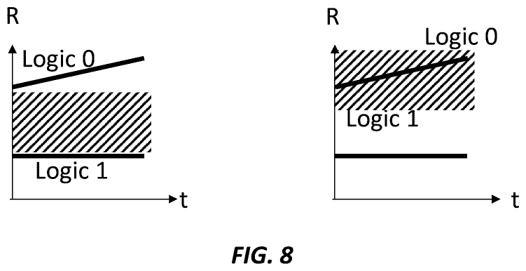

In one or more embodiments, in the programming step, the zeroes and ones are both programmed in a near-reset state. For example, FIG. 8 shows conventional programming on the left and programming in accordance with an aspect of the invention on the right. The dynamic range is shown in cross-hatch in each case. In the example on the right, both 0 and 1 are near the band. For example, for PCM, reset at around 1 MΩ (higher is better but a little lower is acceptable in some instances). Furthermore, for PCM, set can usually be 10-100 kΩ. In the prior art, the Logic 1 is at the low resistance (set) state and the Logic 0 is at the high-resistance state. In the example on the right, 0 and 1 both have at least 0.7 MΩ (for PCM), or even at least 0.8 MΩ, at least 0.9 MΩ, or at least 1 MΩ.

In another aspect, an exemplary system includes a memory array including a plurality of word lines 3006 and a plurality of bit lines 3010 intersecting the plurality of word lines at a plurality of cell locations. A plurality of cells are respectively located at the plurality of cell locations. Each cell of the plurality of cells in turn includes at least one phase change memory device 3001 having a predetermined drift. A model control 3097, 7779 is coupled to the word lines and an array program and read circuit 3095 is coupled to the bit lines. The model control and the array program and read circuit are cooperatively configured to cause the phase change memory array to be programmed with a model including a plurality of zeroes and ones. The zeroes and ones are both programmed in a near-reset state as shown in FIG. 8. The model control and the array program and read circuit are further cooperatively configured to cause the phase change memory array to carry out inferencing with the programmed array for no more than a predetermined time period. The phase change memory array is able to carry out accurate inferencing with the programmed array for no more than a predetermined time period because the ones degrade to zeroes after the predetermined time period due to the predetermined drift, to prevent further inferencing after the predetermined time period has elapsed.

In one or more embodiments, each of the cells is electrically connected to a corresponding bit line and selectively grounded under control of a corresponding one of the word lines as discussed elsewhere herein.

One or more embodiments further include a network, where the memory array is located on an edge computing device that is coupled to the network. For example, referring to FIG. 9, the memory array could be on an end user device 103 (or within the public cloud 105).

In a non-limiting example, the model includes a hyperdimensional (HD) model. See FIG. 3.

On the other hand, in other non-limiting example(s), the model includes a deep neural network (DNN) model selected from the group consisting of a residual neural network, a long short-term memory, and a transformer-based model. See FIG. 7.

Refer now to FIG. 9. Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code 200 involved in performing the inventive methods, such as an edge application or cloud application that uses an array in accordance with aspects of the invention. Block 200 also represents code used in the synthesis of digital circuits such as control circuits, in which case the end user device could be semiconductor fabrication equipment. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 9. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed use of phase change memory (PCM) drift to erase hyperdimensional (HD) model for secure edge computing.

An integrated circuit in accordance with aspects of the present inventions can be employed in essentially any application and/or electronic system where one or more aspects of the disclosed use of phase change memory (PCM) drift to erase hyperdimensional (HD) model for secure edge computing would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F. R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A system comprising:
a memory array comprising:
a plurality of word lines;
a plurality of bit lines intersecting the plurality of word lines at a plurality of cell locations; and
a plurality of cells respectively located at the plurality of cell locations; wherein each cell of the plurality of cells in turn comprises:
a first phase change memory device having a first drift; and
a second phase change memory device having a second drift;
wherein the first drift is higher than the second drift.

2. The system of claim 1, wherein the first phase change memory device does not have a liner and wherein the second phase change memory device has a liner.

3. The system of claim 1, wherein the first phase change memory device includes GST phase change material and wherein the second phase change memory device includes superlattice phase change material.

4. The system of claim 1, wherein the first and second phase change memory devices are connected in parallel and each of the cells is electrically connected to a corresponding bit line and selectively grounded under control of a corresponding one of the word lines.

5. The system of claim 4, further comprising a model control coupled to the word lines and configured to select given ones of the cells for reset.

6. The system of claim 5, further comprising an array program and read circuit coupled to the bit lines and configured to program the cells and read out inferencing results.

7. The system of claim 6, wherein the model control comprises a hyperdimensional (HD) encoding control.

8. The system of claim 6, wherein the first and second phase change memory devices each include a top electrode, a bottom electrode, and phase change material.

9. The system of claim 6, wherein the array program and read circuit is further configured to program the cells with weights represented by a difference between the first and second phase change memory devices.

10. The system of claim 9, further comprising a network, wherein the memory array is located on an edge computing device that is coupled to the network.

11. A method of operating a phase change memory array, comprising:
providing a phase change memory array including:
a plurality of word lines;
a plurality of bit lines intersecting the plurality of word lines at a plurality of cell locations; and
a plurality of cells respectively located at the plurality of cell locations; wherein each cell of the plurality of cells in turn includes at least one phase change memory device having a predetermined drift;
programming the phase change memory array with a model including a plurality of zeroes and ones;
carrying out inferencing with the programmed array for no more than a predetermined time period; and
deliberately allowing the ones to degrade to zeroes after the predetermined time period due to the predetermined drift to prevent further inferencing after the predetermined time period has elapsed.

12. The method of claim 11, wherein, in the step of programming the phase change memory array with the model, the model comprises a hyperdimensional (HD) model.

13. The method of claim 11, wherein, in the step of programming the phase change memory array with the model, the model comprises a deep neural network (DNN) model selected from the group consisting of a residual neural network, a long short-term memory, and a transformer-based model.

14. The method of claim 11, further comprising locating the phase change memory array on an edge computing device that is coupled to a network.

15. The method of claim 11, wherein, in the programming step, the zeroes and ones are both programmed in a near-reset state.

16. A system comprising:
a memory array comprising:
a plurality of word lines;
a plurality of bit lines intersecting the plurality of word lines at a plurality of cell locations; and
a plurality of cells respectively located at the plurality of cell locations; wherein each cell of the plurality of cells in turn includes at least one phase change memory device having a predetermined drift; and
a model control coupled to the word lines and an array program and read circuit coupled to the bit lines, wherein the model control and the array program and read circuit are cooperatively configured to cause:
the phase change memory array to be programmed with a model including a plurality of zeroes and ones, wherein the zeroes and ones are both programmed in a near-reset state; and
the phase change memory array to carry out inferencing with the programmed array for no more than a predetermined time period;
whereby the phase change memory array is able to carry out accurate inferencing with the programmed array for no more than a predetermined time period because the ones degrade to zeroes after the predetermined time period due to the predetermined drift to prevent further inferencing after the predetermined time period has elapsed.

17. The system of claim 16, wherein each of the cells is electrically connected to a corresponding bit line and selectively grounded under control of a corresponding one of the word lines.

18. The system of claim 17, further comprising a network, wherein the memory array is located on an edge computing device that is coupled to the network.

19. The system of claim 17, wherein the model comprises a hyperdimensional (HD) model.

20. The system of claim 17, wherein the model comprises a deep neural network (DNN) model selected from the group consisting of a residual neural network, a long short-term memory, and a transformer-based model.
